(19) United States
(12) Patent Application Publication
(10) Pub. No.: US 2021/0269716 A1
(43) Pub. Date: Sep. 2, 2021

(54) Silicon Etching Solution, Method for Manufacturing Silicon Device Using Same, and Substrate Treatment Method

(71) Applicants: Tokuyama Corporation, Yamaguchi (JP); Screen Holdings Co., Ltd., Kyoto (JP)

(72) Inventors: Yoshiki Seike, Yamaguchi (JP); Seiji Tono, Yamaguchi (JP); Manami Oshio, Yamaguchi (JP); Kenji Kobayashi, Kyoto (JP); Sei Negoro, Kyoto (JP)

(21) Appl. No.: 17/186,057

(22) Filed: Feb. 26, 2021

(30) Foreign Application Priority Data
Feb. 27, 2020 (JP) 2020-032471
Jun. 3, 2020 (JP) 2020-097214

(51) Int. Cl. C09K 13/00; H01L 21/306; H01L 21/3213; H01L 21/687

(52) U.S. Cl. CPC C09K 13/00; H01L 21/68764; H01L 21/32134; H01L 21/30604

(57) ABSTRACT

An isotropic silicon etching solution contains a quaternary ammonium hydroxide; water; and the at least one compound selected from the group consisting of compounds represented by the following Formulas (1) and (2), in which the following Conditions 1 and 2 are satisfied.

R¹O—(CₘH₂ₘO)ₙ—R² (1)

In the formula, R¹ is a hydrogen atom or an alkyl group having 1 to 3 carbon atoms, R² is a hydrogen atom or an alkyl group having 1 to 6 carbon atoms, m is an integer of 2 to 6, and n is 1 to 3. With the proviso that, R¹ and R² are not hydrogen atoms at the same time, and when m=2, a total number (n+C¹+C²) of n, the number of carbon atoms (C¹) of R¹, and the number of carbon atoms (C²) of R² is 5 or more.

HO—(C₂H₄O)ₚ—H (2)

In the formula, p is an integer of 15 to 1,000.

Condition 1: 0.2≤etching rate ratio (R₁₁₀/R₁₀₀)≤1

Condition 2: 0.8≤etching rate ratio (R₁₁₀/R₁₁₁)≤4

R₁₀₀ indicates an etching rate for a 100 plane of a silicon single crystal, R₁₁₀ indicates an etching rate for a 110 plane of the silicon single crystal, and R₁₁₁ indicates an etching rate for a 111 plane of the silicon single crystal.

This U.S. patent application claims priority to Japanese patent document 2020-032471 filed on 27 Feb. 2020 and Japanese patent document 2020-097214 filed on 3 Jun. 2020, the entireties of which are incorporated herein by reference.

### BACKGROUND OF THE INVENTION

### Field of the Invention

The present invention relates to a silicon etching solution used in surface processing and an etching step when manufacturing various silicon devices. The present invention also relates to a method for manufacturing a silicon device using the etching solution. The present invention further relates to a substrate treatment method using the etching solution. Examples of a substrate includes a semiconductor wafer, a glass substrate for a liquid crystal display device, a glass substrate for a plasma display, a glass or ceramic substrate for a magnetic or optical disk, a glass substrate for an organic EL, and a glass substrate or silicon substrate for a solar cell.

### Background Of The Invention

In consideration of selectivity for a silicon oxide film and a silicon nitride film, alkaline etching may be used in a process for manufacturing a semiconductor using silicon. Here, the selectivity means a property that exhibits a particularly high etching performance with respect to a specific material. For example, at the time of etching a substrate having a silicon film and another film (for example, a silicon oxide film), when only the silicon film is etched and the silicon oxide film is not etched, selectivity for silicon is high. As an alkali, NaOH, KOH, and tetramethylammonium hydroxide (hereinafter, sometimes referred to as TMAH), which have low toxicity and are easy to handle, are used alone. Among them, TMAH has an etching rate for a silicon oxide film as low as one order of magnitude than that in the case of using NaOH or KOH, and is preferably used in a case where, in particular, a silicon oxide film, which is cheaper than a silicon nitride film, is used as a mask material.

In a semiconductor device, a demand for etching is becoming stricter due to multi-layering of a memory cell and densification of a logic device. In a case of silicon etching with an alkali, unlike etching with a hydrofluoric acid-nitric acid aqueous solution, crystal anisotropy is exhibited. The crystal anisotropy means a property (etching anisotropy) that an etching rate differs depending on a crystal orientation of silicon. Utilizing this property, alkaline etching of single crystal silicon is used for manufacturing a silicon device having a complicated three-dimensional structure. Meanwhile, polysilicon contains single crystal silicon grains (single crystal grains), and thus, there are problems that when there is etching anisotropy, the etching rate differs due to a difference in exposed crystal orientations of the single crystal grains, uniform etching cannot be performed, surface roughness is likely to occur, and specific single grains are hard to be etched and may remain after etching.

In recent years, a silicon etching process is often used in a semiconductor manufacturing process. A process for manufacturing a charge storage type memory is described as an example of the silicon etching process. The charge storage type memory includes, for example, as shown in FIG. 4, a substrate W having a multi-layered film 91 including a plurality of polysilicon films P1, P2, and P3 and a plurality of silicon oxide films O1, O2, and O3, and a manufacturing process of the charge storage type memory includes an etching process for the multi-layered film 91. During the etching, a step of etching only the polysilicon films while remaining the silicon oxide films is included, and an etching solution is supplied to a concave portion 92 provided in the substrate W to selectively etch the polysilicon films P1, P2, and P3. At this time, the silicon oxide films O1, O2, and O3 remain without being etched. The charge storage type memory operates as a memory by storing charges in the polysilicon films. An amount of stored charges depends on a volume of the polysilicon film. Therefore, in order to realize a design capacity, it is necessary to strictly control the volume of the polysilicon films. However, when the etching rate differs depending on the crystal orientations of the single crystal grains as described above, the polysilicon films cannot be uniformly etched, which makes it difficult to manufacture a device.

As described above, the etching with the hydrofluoric acid-nitric acid aqueous solution can be performed isotropically regardless of the crystal orientation of silicon, and can uniformly etch single crystal silicon, polysilicon, and amorphous silicon. That is, the hydrofluoric acid-nitric acid aqueous solution does not exhibit crystal anisotropy in etching of silicon. However, the hydrofluoric acid-nitric acid aqueous solution has a small etching selective ratio of silicon to the silicon oxide film, and cannot be used in a semiconductor manufacturing process in which the silicon oxide film remains as described above.

An alkaline etching solution has selectivity for the silicon oxide film and the silicon film and selectively etches the silicon film. Regarding etching using an alkali, Japanese Patent Laid-Open No. 2010-141139 (Patent Literature 1) discloses an etching solution for a silicon substrate for a solar cell, which contains an alkali hydroxide, water, and a polyalkylene oxide alkyl ether. Japanese Patent Laid-Open No. 2012-227304 (Patent Literature 2) discloses an etching solution for a silicon substrate for a solar cell, which contains an alkaline compound, an organic solvent, a surfactant, and water. In Patent Literature 2, TMAH is shown as an example of the alkaline compound, and a polyalkylene oxide alkyl ether is shown as the organic solvent, but the alkaline compound actually used is sodium hydroxide or potassium hydroxide.

International Publication No. WO 2017/169834 (Patent Literature 3) discloses a developing solution containing a quaternary alkyl ammonium hydroxide, a nonionic surfactant, and water. A polyalkylene oxide alkyl ether is shown as an example of the nonionic surfactant, but a nonionic surfactant having high surface activity, such as acetylene glycol-based surfynol (trade name), is actually used.

Denso Technical Review, Yamashita et al., 2001, Vol. 6, No. 2, p. 94-99 (Non-Patent Literature 1) describes a method of being able to etch silicon isotropically by oxidizing a silicon surface by applying a voltage and dissolving an oxide film of the silicon surface with a KOH aqueous solution.

Japanese Patent Laid-Open No. 2019-50364 (Patent Literature 4) discloses an etching solution containing water, a quaternary alkyl ammonium hydroxide, and a water-miscible solvent, and describes tripropylene glycol methyl ether, etc., as the water-miscible solvent.

### PRIOR ART DOCUMENTS

[Patent Literature 1] Japanese Patent Laid-Open No. 2010-141139
[Patent Literature 2] Japanese Patent Laid-Open No. 2012-227304
[Patent Literature 3] International Publication No. WO 2017/169834
[Patent Literature 4] Japanese Patent Laid-Open No. 2019-50364

### NON-PATENT LITERATURES

[Non-Patent Literature 1] Denso Technical Review, Yamashita et al., 2001, Vol. 6, No. 2, p. 94-99

### SUMMARY OF THE INVENTION

In the etching solutions of Patent Literature 1 and Patent Literature 2, since NaOH and KOH are used as the alkaline compound, an etching rate for a silicon oxide film is high. Therefore, the silicon oxide film that should remain as a mask material and a part of a pattern structure is also etched, and it is impossible to selectively etch only a polysilicon film. Further, objects of the etching solutions of Patent Literatures 1 and 2 are to enhance crystal anisotropy and roughen a surface, and thus, the polysilicon film cannot be uniformly etched. An object of the developing solution of Patent Literature 3 is not precision etching of silicon, and therefore, uniformity of etching of a polysilicon film is not considered by any means. The nonionic surfactant actually used is surfynol, etc., which has high surface activity, covers a surface of the polysilicon film, and impairs the etching using an alkali for the polysilicon film, so that the polysilicon film cannot be etched with high accuracy. Next, in Non-Patent Literature 1, silicon can be etched isotropically, but silicon is not directly dissolved. In detail, the oxide film obtained by oxidization by applying the voltage is etched with the KOH aqueous solution, so that there is no etching selective ratio of silicon to the silicon oxide film. Further, the etching solution described in Patent Literature 4 is a chemical solution that can selectively remove silicon from silicon-germanium, and there is no description about isotropically etching silicon.

Therefore, an object of the present invention is to provide a silicon etching solution that can prevent crystal anisotropy and enable the same uniform etching treatment regardless of crystal orientations of single crystal grains in a polysilicon film. An object of a preferred aspect of the present invention is to provide a method of adjusting a degree of influence of crystal anisotropy on an etching rate during silicon etching by adjusting a composition ratio of the silicon etching solution.

As a result of diligent efforts, the present inventors have found that the above problem can be solved by incorporating a compound represented by Formula (1) or Formula (2) in a silicon etching solution containing a quaternary ammonium hydroxide and water.

That is, a first invention relates to an isotropic silicon etching solution, containing: a quaternary ammonium hydroxide; water; and at least one compound selected from the group consisting of compounds represented by the following Formulas (1) and (2), in which the following Conditions 1 and 2 are satisfied.

R¹O—(CₘH₂ₘO)ₙ—R² (1)

(In the formula, R¹ is a hydrogen atom or an alkyl group having 1 to 3 carbon atoms, R² is a hydrogen atom or an alkyl group having 1 to 6 carbon atoms, m is an integer of 2 to 6, and n is 1 to 3. With the proviso that R¹ and R² are not hydrogen atoms at the same time, and when m=2, a total number (n+C¹+C²) of n, the number of carbon atoms (C¹) of R¹, and the number of carbon atoms (C²) of R² is 5 or more.)

HO—(C₂H₄O)ₚ—H (2)

(In the formula, p is in a range of 15 to 1,000.)

Condition 1: 0.2≤etching rate ratio (R₁₁₀/R₁₀₀)≤1

Condition 2: 0.8≤etching rate ratio (R₁₁₀/R₁₁₁)≤4

(In the above conditions, R₁₀₀ indicates an etching rate for a 100 plane of a silicon single crystal, R₁₁₀ indicates an etching rate for a 110 plane of the silicon single crystal, and R₁₁₁, indicates an etching rate for a 111 plane of the silicon single crystal.)

In the first invention, a concentration of the quaternary ammonium hydroxide is preferably 0.1 mass % to 25 mass %, and a concentration of at least one compound selected from the compounds represented by Formula (1) and Formula (2) is preferably 0.001 wt % to 40 wt %.

In the first invention, the concentration of the quaternary ammonium hydroxide is more preferably 0.5 mass % to 25 mass %, and the concentration of the at least one compound selected from the compounds represented by Formula (1) and Formula (2) is more preferably 0.001 wt % to 20 wt %.

The etching rate ratio (R₁₁₀/R₁₀₀) of the silicon etching solution of the first invention is preferably 0.3 to 1 and the etching rate ratio (R₁₁₀/R₁₁₁) is preferably 0.8 to 3. When the etching rate ratio is within the above range, the etching rate becomes substantially constant regardless of a crystal orientation, surface roughness is decreased, and uniform etching is possible.

A second invention relates to a substrate treatment method of treating a silicon wafer and/or a substrate including a polysilicon film and an amorphous silicon film by using the isotropic silicon etching solution of the first invention.

A third invention relates to a method for manufacturing a silicon device, including a step of etching a silicon wafer, a polysilicon film, or an amorphous silicon film, in which etching is performed by using the silicon etching solution of the first invention.

In the present invention, the etching rate ratio is a ratio of etching rates to silicon substrates having different crystal orientations, and Condition 1 is the etching rate ratio between the 110 plane and the 100 plane (etching rate ratio (R₁₁₀/R₁₀₀)), and Condition 2 is the etching rate ratio between the 110 plane and the 111 plane (etching rate ratio (R₁₁₀/R₁₁₁)). When the etching rate ratio is within the above range, it means that the etching rate is not easily influenced by the crystal orientation during the etching. When the etching rate ratios of Conditions 1 and 2 are close to 1, the etching rate is less likely to be influenced by the crystal orientation during the etching, and etching can be performed more isotropically.

A study of the present inventors has found that, when a conventional silicon etching solution containing a quaternary ammonium hydroxide and water contains the at least one compound selected from the compounds represented by Formula (1) and Formula (2), as shown in FIG. 1, the etching rate for silicon is lower, but a difference in etching rate due to a difference in crystal orientation is lower, as compared with a silicon etching solution that does not contain the at least one compound selected from the compounds represented by Formula (1) and Formula (2). The silicon etching solution that does not contain the at least one compound selected from the compounds represented by Formula (1) and Formula (2) has a larger etching rate in an order of the 110 plane and the 100 plane, and the smallest etching rate for the 111 plane. When the at least one compound selected from the compounds represented by Formula (1) and Formula (2) is contained, the etching rate of each crystal face decreases, but a decrease in etching rate on the 111 plane is smaller than the decreases in etching rate on the 100 and 110 planes, so that the etching rate of each crystal face approaches the same level. At this time, when the amounts of the quaternary ammonium hydroxide and the at least one compound selected from the compounds represented by Formula (1) and Formula (2) are adjusted, a silicon etching solution that is less likely to be influenced by the crystal orientation and can etch silicon more uniformly can be obtained.

A substrate treatment method according to a first embodiment using the silicon etching solution of the present invention includes a substrate holding step of holding a substrate in a horizontal posture, and a treatment solution supplying step of supplying the isotropic silicon etching solution of the present invention to an upper surface of the substrate while rotating the substrate around a vertical rotation axis passing through a central portion of the substrate.

A substrate treatment method according to a second embodiment using the silicon etching solution of the present invention includes a substrate holding step of holding a plurality of substrates in an upright posture, and a step of immersing, in the upright posture, the substrates in the isotropic silicon etching solution of the present invention stored in a treatment tank.

The etching rate of the silicon etching solution of the present invention is less likely to be influenced by the crystal orientation of silicon, and an isotropic etching treatment is possible regardless of the crystal orientation appearing on an etching treatment surface of a polysilicon film or a single crystal.

By adjusting a composition ratio of the silicon etching solution, the etching rate can be adjusted with respect to the crystal orientation of silicon, and a silicon etching solution having a desired etching rate ratio can be prepared.

### BRIEF DESCRIPTION OF THE DRAWINGS

FIG. 1 is a graph showing a relation between a concentration of at least one compound selected from compounds represented by Formula (1) and Formula (2) and an etching rate for each crystal face of a silicon substrate.

FIG. 2 is a schematic top view of a substrate treatment device used in a first embodiment. FIG. 3 is a schematic cross-sectional view of a substrate treatment unit used in the first embodiment.

FIG. 4 is a schematic cross-sectional view showing a substrate W to be etched.

FIG. 5 is an example of an etching treatment flow in the first embodiment.

FIG. 6 is a schematic cross-sectional view showing another substrate W2 to be etched.

FIG. 7 is a schematic top view of a substrate treatment device used in a second embodiment.

FIG. 8 is a schematic cross-sectional view of a substrate treatment unit used in the second embodiment.

FIG. 9 is an example of an etching treatment flow in the second embodiment.

### DETAILED DESCRIPTION OF THE INVENTION

An isotropic silicon etching solution of the present invention contains a quaternary ammonium hydroxide, water, and at least one compound selected from the group consisting of compounds represented by the following Formulas (1) and (2), and satisfies the following Conditions 1 and 2.

R¹O—(CₘH₂ₘO)ₙ—R² (1)

(In the formula, R¹ is a hydrogen atom or an alkyl group having 1 to 3 carbon atoms, R² is a hydrogen atom or an alkyl group having 1 to 6 carbon atoms, m is an integer of 2 to 6, and n is 1 to 3. With the proviso that R¹ and R² are not hydrogen atoms at the same time, and when m=2, a total number (n+C¹+C²) of n, the number of carbon atoms (C¹) of R¹, and the number of carbon atoms (C²) of R² is 5 or more.)

HO—(C₂H₄O)ₚ—H (2)

(In the formula, p is in a range of 15 to 1,000.)

Condition 1: 0.2≤etching rate ratio (R₁₁₀/R₁₀₀)≤1

Condition 2: 0.8≤etching rate ratio (R₁₁₀/R₁₁₁)≤4

(In the above conditions, R₁₀₀ indicates an etching rate for a 100 plane of a silicon single crystal, R₁₁₀ indicates an etching rate for a 110 plane of the silicon single crystal, and R₁₁₁ indicates an etching rate for a 111 plane of the silicon single crystal. The etching rate is measured by a method described in Examples.)

As the quaternary ammonium hydroxide, various quaternary ammonium hydroxides that have been conventionally used as a component of the silicon etching solution are used. The quaternary ammonium hydroxide is represented by NR₄⁺·OH⁻. R is usually an alkyl group or an aryl group, and four Rs may be the same as or different from each other. The alkyl group or the aryl group may have a substitution group such as a hydroxy group. Preferred examples of the quaternary ammonium hydroxide include a quaternary alkyl ammonium hydroxide in which four Rs are alkyl groups, and an ammonium compound in which a hydroxy group is bonded to an alkyl group of a quaternary alkyl ammonium hydroxide, for example, trimethyl-2-hydroxyethylammonium hydroxide (choline hydroxide), dimethylbis(2-hydroxylethyl)ammonium hydroxide, and methyltris(2-hydroxylethyl)ammonium hydroxide.

As the quaternary alkyl ammonium hydroxide, tetramethylammonium hydroxide (TMAH), tetraethylammonium hydroxide (TEAH), tetrapropylammonium hydroxide, or tetrabutylammonium hydroxide can be used without particular limitation. Among these quaternary alkyl ammonium hydroxides, a quaternary alkyl ammonium hydroxide in which an alkyl group has 1 to 4 carbon atoms and all of alkyl groups are the same are preferred. In particular, it is most preferable to use TMAH because of a high etching rate for silicon.

A concentration of the quaternary ammonium hydroxide is not particularly different from that of a conventional silicon etching solution, and when the concentration is in a range of 0.1 mass % to 25 mass %, an excellent etching effect can be obtained without causing crystal precipitation, which is preferred. The concentration of the quaternary ammonium hydroxide is more preferably in a range of 0.5 mass % to 25 mass %.

The silicon etching solution of the present invention is characterized by containing the at least one compound selected from compounds represented by the following Formula (1) and Formula (2).

R¹O—(CₘH₂ₘO)ₙ—R² (1)

In the above Formula (1), R¹ is a hydrogen atom or an alkyl group having 1 to 3 carbon atoms, R² is ahydrogen atom or an alkyl group having 1 to 6 carbon atoms, m is an integer of 2 to 6, and n is 1 to 3. With the proviso that R¹ and R² are not hydrogen atoms at the same time. When m=2, a total number (n+C¹+C²) of n, the number of carbon atoms (C¹) of R¹, and the number of carbon atoms (C²) of R² is 5 or more.)

R¹ is preferably a hydrogen atom or a methyl group, R² is preferably a propyl group or a butyl group, and m is preferably 2 or 3.

Specific examples of the compound represented by the above Formula (1), which is particularly preferably used in the present invention, include ethylene glycol monobutyl ether, diethylene glycol ethyl methyl ether, diethylene glycol diethyl ether, diethylene glycol monobutyl ether, propylene glycol monomethyl ether, propylene glycol monoethyl ether, propylene glycol monopropyl ether, propylene glycol monobutyl ether, propylene glycol dimethyl ether, dipropylene glycol monomethyl ether, dipropylene glycol monopropyl ether, dipropylene glycol dimethyl ether, triethylene glycol monobutyl ether, and tripropylene glycol monomethyl ether. Among them, ethylene glycol monobutyl ether, diethylene glycol monobutyl ether, propylene glycol monoethyl ether, propylene glycol monopropyl ether, propylene glycol monobutyl ether, dipropylene glycol monopropyl ether, triethylene glycol monobutyl ether, and tripropylene glycol monomethyl ether are preferred.

HO—(C₂H₄O)ₚ—H (2)

In the above Formula (2), p is in a range of 15 to 1,000. It is noted that p is an average value. Therefore, the compound represented by Formula (2) may include a small amount of compounds in which p is 14 or less or p is more than 1,000. However, among the compounds represented by Formula (2), a proportion of a compound in which p is out of the above range is 2% or less, and preferably 0%. Examples of the compound represented by the above Formula (2), which is particularly preferably used in the present invention, include all polyethylene glycols in which p=15 to 1,000 in Formula (2). If p is less than 15, an effect of the present invention is not exhibited, and if p is more than 1,000, a viscosity at the time of mixing becomes high, which makes it difficult to use. Among these polyethylene glycols, those in which p=30 to 500 is preferred from viewpoints of viscosity and handling. Specific examples thereof include, but are not limited to, polyethylene glycol 1000 (p=about 22), polyethylene glycol 1500 (p=about 33), polyethylene glycol 1540 (p=about 35), polyethylene glycol 2000 (p=about 45), polyethylene glycol 4000 (p =about 90), and polyethylene glycol 20000 (p=about 450), which are manufactured by FUJIFILM Wako Pure Chemical Corporation.

Regarding the compounds represented by Formula (1) or Formula (2), one kind may be used alone, or a plurality of different kinds of compounds may be mixed and used. For example, mixture of propylene glycol monomethyl ether and propylene glycol monopropyl ether, mixture of diethylene glycol ethyl methyl ether and polyethylene glycol 1000, and mixture g of polyethylene glycol 1000 and polyethylene glycol 4000 can be listed.

As described above, when the compound represented by Formula (1) or Formula (2) is contained in a silicon etching solution containing a quaternary ammonium hydroxide and water, a difference in etching rate due to a difference in crystal orientation of silicon decreases. A silicon etching solution that does not contain the compound represented by Formula (1) or Formula (2) has a larger etching rate in an order of the 110 plane and the 100 plane, and the smallest etching rate for the 111 plane. When the compound represented by Formula (1) or Formula (2) is contained, the etching rate for each crystal face decreases, but a decrease in etching rate for the 111 plane is smaller than decreases in etching rate for the 100 and 110 planes, so that the etching rate for each crystal face approaches the same level.

When the at least one compound selected from the compounds represented by Formula (1) and Formula (2) is contained and Conditions 1 and 2 are satisfied, crystal anisotropy during silicon etching can be prevented, isotropic etching can be performed, and the same etching treatment is possible regardless of a silicon wafer, a polysilicon film, or an amorphous silicon film.

In order to satisfy the above Conditions 1 and 2, it is sufficient to adjust a content of the at least one compound selected from the compounds represented by Formula (1) and Formula (2). At this time, when an upper limit or lower limit of Conditions 1 and 2 is deviated, even when etching can be performed uniformly with respect to a certain crystal orientation, etching is non-uniformly performed with respect to other crystal orientations, which means that an influence of the orientation of single crystal grains in the polysilicon film cannot be prevented, and uniform etching cannot be performed.

When the content of the at least one compound selected from the compounds represented by Formula (1) and Formula (2) is adjusted, a silicon etching solution influenced by a desired crystal orientation can be obtained.

A concentration of the at least one compound selected from the compounds represented by the above Formula (1) and Formula (2) is preferably 40 mass % or less, more preferably less than 20 mass %, still more preferably less than 15 mass %, and particularly preferably 10 mass % or less, based on a total mass of the etching solution. The concentration of the at least one compound selected from the compounds represented by the above Formula (1) and Formula (2) is preferably 0.001 mass % or more. When the concentration of the at least one compound selected from the compounds represented by the above Formula (1) and Formula (2) is within the above range, a difference in etching rate depending on the crystal orientation becomes small, and thus, an influence of orientation the single crystal grains in polysilicon is decreased, and a uniform etching treatment is possible.

A total concentration of the quaternary ammonium hydroxide and the at least one compound selected from the compounds represented by Formula (1) and Formula (2) is preferably 45 mass % or less, more preferably 40 mass % or less, and still more preferably 35 mass % or less, and a lower limit is preferably 0.101 mass %, and more preferably 0.501 mass %.

Regarding a mass ratio (quaternary ammonium hydroxide/compound) of the quaternary ammonium hydroxide to the at least one compound selected from the compounds represented by Formula (1) and Formula (2), the compound represented by Formula (1) is preferably 0.05 to 10, more preferably 0.1 to 5, and the compound represented by Formula (2) is preferably 0.5 to 1,000, more preferably 1 to 500.

When the compound represented by Formula (1) is used alone, a concentration thereof is preferably 0.1 mass % to 40 mass %, and more preferably 0.1 mass % to 20 mass %, based on the total mass of the etching solution. When the compound represented by Formula (2) is used alone, a concentration thereof is preferably 0.001 mass % to 10 mass %, and more preferably 0.001 mass % to 5 mass %, based on the total mass of the etching solution.

When the compound represented by Formula (1) and the compound represented by Formula (2) are used in combination, a mass ratio (compounds of Formula (1)/compound of Formula (2)) is preferably 0.05 to 2,000, more preferably 0.1 to 1,000, and a total amount thereof is preferably within the above range.

In addition to the quaternary ammonium hydroxide and the at least one compound selected from the compounds represented by Formula (1) and Formula (2), a surfactant and the like may be added to the silicon etching solution as long as the objects of the present invention are not impaired, but the surfactant and the like may influence etchability, and are thus preferably 1 mass % or less, and more preferably not contained. Therefore, the silicon etching solution preferably substantially consists of the quaternary ammonium hydroxide, the at least one compound selected from the compounds represented by Formula (1) and Formula (2), and water, and a content of components other than these components is preferably 1 mass % or less, and more preferably components other than these components are not contained. That is, it is preferable that a total amount of a balance of the silicon etching solution other than the quaternary ammonium hydroxide and the at least one compound selected from the compounds represented by Formula (1) and Formula (2) is water.

A mechanism of reducing the influence of the crystal anisotropy of silicon in etching by adding the compound represented by the above Formula (1) or Formula (2) is not always clear. However, the present inventors consider as follows. The compound represented by the above Formula (1) or Formula (2) can be considered as a nonionic surfactant having relatively low surface activity. The compound represented by the above Formula (1) or Formula (2) has surface activity and adheres to a polysilicon surface to temporarily protect the surface of polysilicon. As a result, a contact between the quaternary ammonium and the surface of silicon, i.e., the 110 plane or the 100 plane, having a high etching rate is obstructed, and etching is prevented. However, the compound represented by Formula (1) or Formula (2) has relatively low surface activity, and is thus released from the surface of silicon. As a result, quaternary ammonium comes into contact with the surface of silicon and etching is performed. Adhesion and release of the compound represented by Formula (1) or Formula (2) to the surface of polysilicon are repeated, and the etching proceeds slowly during this period. Meanwhile, although the compounds adhere to the surface of silicon, i.e., the 111 plane, an atomic void radius on the 111 plane is smaller than those of the 110 plane and the 100 plane, and it is considered that the compound of the above Formula (1) or Formula (2) is hard to penetrate. Therefore, it is considered that the obstruction of contact between the surface of silicon and quaternary ammonium is smaller than those of the 110 plane and the 100 plane, and a degree of etching prevention is also decreased. As a result, the etching rate is slowed down, but the influence of the crystal orientation is considered to be reduced.

Meanwhile, when a nonionic surfactant having high surface activity is used instead of the compound represented by Formula (1) or Formula (2), the surfactant firmly adheres to the surface of polysilicon, a contact between the surface of polysilicon and the etching solution is obstructed, which makes it difficult to perform the etching.

The etching rate ratio (R₁₁₀/R₁₀₀) is preferably 0.3 to 1 and the etching rate ratio (R₁₁₀/R₁₁₁) is preferably 0.8 to 3.5. When the etching rate ratio is within the above range, the etching rate is substantially constant regardless of the crystal orientation, surface roughness is decreased, and uniform etching is possible.

The silicon etching solution of the present invention can be easily prepared by mixing and dissolving a predetermined amount of the at least one compound selected from the compounds represented by Formula (1) and Formula (2) in a quaternary ammonium hydroxide aqueous solution having a predetermined concentration. At this time, instead of directly mixing the at least one compound selected from the compounds represented by Formula (1) and Formula (2), an aqueous solution of the at least one compound selected from the compounds represented by Formula (1) and Formula (2) having a predetermined concentration may be prepared in advanced and mixed with the quaternary ammonium hydroxide.

The silicon etching solution of the present invention has low toxicity and is easy to handle, which are features of a quaternary ammonium hydroxide aqueous solution-based silicon etching solution, and has an advantage that an inexpensive silicon oxide film can be used as a mask material or a pattern structure having a silicon oxide film that should be remained can be used. Compared with a conventional quaternary ammonium hydroxide aqueous solution-based silicon etching solution, is the invention realize less variation in etching rate for silicon due to the difference in crystal orientation. More specifically, there is a characteristic that the influence of the orientation of single crystal grains in the polysilicon film can be prevented when an etching treatment is performed under the same conditions. Therefore, the silicon etching solution of the present invention can be suitably used as an etching solution at the time of manufacturing various silicon devices by a wet etching technique for silicon, such as processing of a valve, a nozzle, a printer head, and a semiconductor sensor (for example, a diaphragm of a semiconductor pressure sensor or a cantilever of a semiconductor acceleration sensor) for detecting various physical quantities such as a flow rate, a pressure, and an acceleration, and etching of a polysilicon film and an amorphous silicon film which are applied to various devices as materials for a part of a metal wiring and a gate electrode.

When a silicon device is manufactured by using the silicon etching solution of the present invention, wet etching for silicon may be performed according to a conventional method. The method in this case is not particularly different from a case where a conventional silicon etching solution is used, for example, the method can be preferably performed by charging “a silicon wafer whose necessary part is masked with a silicon oxide film or a silicon nitride film”, as an object to be etched, into an etching tank into which a silicon etching solution is introduced, and utilizing a chemical reaction with the silicon etching solution to dissolve an unnecessary part of the silicon wafer.

In a preferred embodiment of the present invention, the silicon etching solution is used for manufacturing a silicon device, including a step of etching a multi-layered body in which a polysilicon film and a silicon oxide film are alternately laminated and which has a concave portion or a through hole penetrating a plurality of films by supplying a silicon etching solution to the concave portion or the through hole to selectively etch the polysilicon film.

In consideration of a desired etching rate, shape and surface condition of silicon after etching, productivity, etc., a temperature of the silicon etching solution during the etching may be appropriately determined from a range of 20° C. to 95° C., and preferably a range of 30° C. to 60° C.

In the wet etching for silicon, an object to be etched may be simply immersed in the silicon etching solution, and an electrochemical etching method can also be adopted by applying a constant potential to the object to be etched.

Examples of an object of the etching treatment in the present invention include a silicon single crystal, polysilicon, and amorphous silicon, and the object may contain a non-object silicon oxide film, silicon nitride film and a metal such as aluminum that is not a target of the etching treatment. For instance the object may include a structure in which a silicon oxide film or a silicon nitride film, and a metal film are laminated on a silicon single crystal to create a pattern shape, a structure in which polysilicon or a resist is formed and coated thereon, and a structure in which a metal portion, such as aluminum, is covered with a protective film and silicon is patterned.

Hereinafter, embodiments of a substrate treatment method using the silicon etching solution of the present invention are described in detail with reference to the accompanying drawings. Examples of a substrate includes a semiconductor wafer, a glass substrate for a liquid crystal display device, a glass substrate for a plasma display, a glass or ceramic substrate for a magnetic or optical disk, a glass substrate for organic EL, and a glass substrate or silicon substrate for a solar cell.

FIG. 2 is a schematic view of a substrate treatment device 1 according to a first embodiment of the present invention, as viewed from the top.

As shown in FIG. 2, the substrate treatment device 1 is a single-wafer processing type that treats disc-shaped substrate W such as semiconductor wafer one by one. The substrate treatment device 1 includes load ports LP holding carriers C for accommodating the substrates W, a plurality of treatment units 2 configured to treat the substrates W conveyed from the carriers C on the load ports LP, a convey robot configured to convey the substrates W between the carriers C on the load ports LP and the treatment units 2, and a control device 3 configured to control the substrate treatment device 1.

The convey robot includes an indexer robot IR configured to carry in and out the substrates W to the carriers C on the load ports LP, and a center robot CR configured to carry in and out the substrates W to the plurality of treatment units 2. The indexer robot IR conveys the substrates W between the load ports LP and the center robot CR, and the center robot CR conveys the substrates W between the indexer robot IR and the treatment units 2. The center robot CR includes a hand H1 that supports the substrates W, and the indexer robot IR includes a hand H2 that supports the substrates W.

The plurality of treatment units 2 form a plurality of towers TW arranged around the center robot CR in a plan view. Each tower TW includes a plurality of (for example, three) treatment units 2 stacked one above another. FIG. 2 shows an example in which four towers TW are formed. The center robot CR can access any tower TW.

FIG. 3 is a schematic view of an inside of each treatment unit 2 provided in the substrate treatment device 1 as viewed horizontally.

Each treatment unit 2 includes a box-shaped chamber 4 having an internal space, a spin chuck 10 rotating one substrate W around a vertical rotation axis passing through a center of the substrate W while holding the substrate W horizontally in the chamber 4, and a tubular treatment cup 20 surrounding the spin chuck 10 around a rotation axis.

The chamber 4 has a box-shaped partition wall 5 provided with a carry-in/out port 6 through which the substrate W passes, and a shutter 7 for opening/closing the carry-in/out port 6.

The spin chuck 10 includes a disc-shaped spin base 12 held in a horizontal posture, a plurality of chuck pins 11 for holding the substrate W in a horizontal posture on the spin base 12, a spin shaft extending downward from a central portion of the spin base 12, and a spin motor 13 configured to rotate the spin base 12 and the plurality of chuck pins 11 by rotating the spin shaft. The spin chuck 10 is not limited to a holding type chuck in which the plurality of chuck pins 11 are brought into contact with an outer peripheral surface of the substrate W, and may be a vacuum type chuck in which the substrate W is held horizontally by adsorbing a back surface (lower surface) of the substrate W, which is a non-device forming surface, to an upper surface of the spin base 12.

The treatment cup 20 includes a plurality of guards 21 configured to receive a liquid discharged outward from the substrate W, and a plurality of cups 22 configured to receive the liquid guided downward by the plurality of guards 21. FIG. 3 shows an example in which two guards 21 and two cups 22 are provided.

Each treatment unit 2 includes a guard elevating unit configured to individually elevate the plurality of guards 21. The guard elevating unit moves the guards 21 at any position from an upper position to a lower position. The guard elevating unit is controlled by the control device 3. The upper position is a position where upper ends of the guards 21 are arranged above a holding position where the substrate W held by the spin chuck 10 is arranged. The lower position is a position where the upper ends of the guards 21 are arranged below the holding position. An annular upper end of a guard ceiling portion corresponds to the upper end of the guard 21. The upper ends of the guards 21 surround the substrate W and the spin base 12 in a plan view.

When a treatment solution is supplied to the substrate W while the spin chuck 10 is rotating the substrate W, the treatment solution supplied to the substrate W is shaken off from the substrate W. When the treatment solution is supplied to the substrate W, the upper end of at least one guard 21 is arranged above the substrate W. Therefore, the treatment solution such as a chemical solution or a rinse solution discharged from the substrate W is received by any of the guards 21 and guided to the cup 22 connected with the guard 21.

A plurality of solution discharge units include a first chemical solution discharge unit 41 configured to discharge a first chemical solution, a second chemical solution discharge unit 42 configured to discharge a second chemical solution, and a rinse solution discharge unit 43 configured to discharge a rinse solution. Further, a plurality of gas discharge unit configured to discharge inert gases may be provided. Each of the plurality of solution discharge units includes a valve configured to control solution discharge, and can start and stop solution discharge. Each of the plurality of solution discharge units includes a drive mechanism, and can move between a treatment position for discharging a solution onto a substrate and a standby position outside the substrate. The valve and the drive mechanism are controlled by the control device 3.

The first chemical solution is a solution including at least one of chemical solutions (for example, hydrofluoric acid, buffered hydrofluoric acid, and aqueous ammonia) that can remove a natural oxide film on the substrate. The first chemical solution is written as DHF in FIG. 3.

The second chemical solution is the silicon etching solution of the present invention. The second chemical solution is written as TMAH COMPOUND in FIG. 3.

The rinse solution to be supplied to the rinse solution discharge unit 43 is pure water (deionized water). The rinse solution to be supplied to the rinse solution discharge unit 43 may be a rinse solution other than pure water. The rinse solution is written as DIW in FIG. 3.

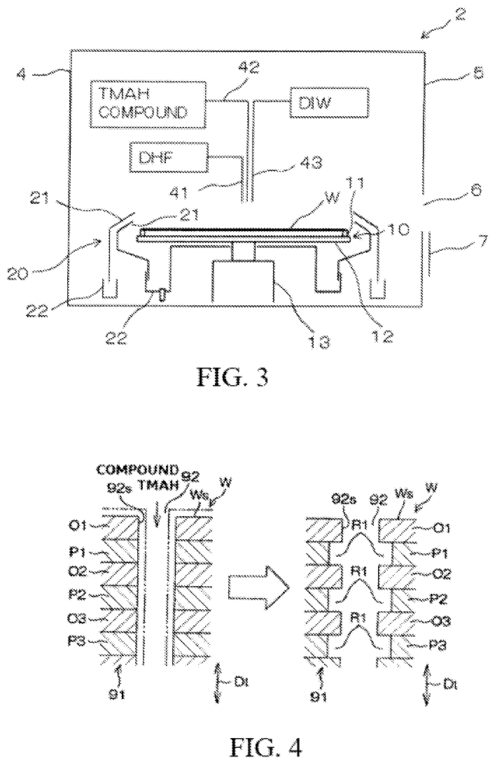

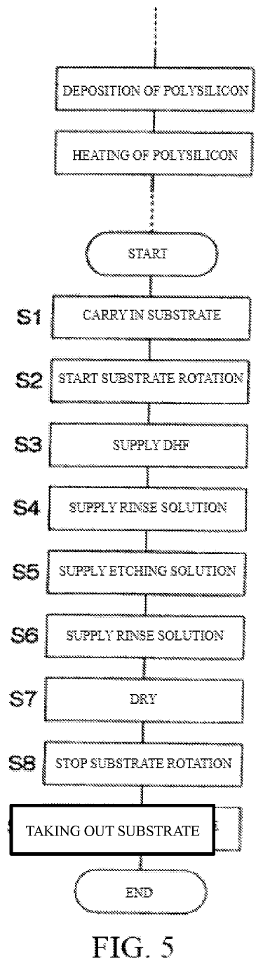

FIG. 4 is a schematic view showing an example of a cross section of the substrate W before and after a treatment shown in FIG. 5 is performed.

The left side in FIG. 4 shows a cross section of the substrate W before the treatment (etching) shown in FIG. 5 is performed, and the right side in FIG. 4 shows a cross section of the substrate W after the treatment (etching) shown in FIG. 5 is performed. As shown on the right side in FIG. 4, when the substrate W is etched, a plurality of recesses R1 recessed in a surface direction of the substrate W (direction orthogonal to a thickness direction Dt of the substrate W) are formed on a side surface 92s of the concave portion 92.

As shown in FIG. 4, the substrate W includes the multi-layered film 91 formed on a base material such as a silicon wafer, and the concave portion 92 recessed from an outermost surface Ws of the substrate W in the thickness direction Dt of the substrate W (direction orthogonal to a surface of the base material of the substrate W). The multi-layered film 91 includes the plurality of polysilicon films P1, P2, and P3 and the plurality of silicon oxide films O1, O2, and O3. The polysilicon films P1 to P3 are examples of the target to be etched, and the silicon oxide films O1 to O3 are examples of an object not to be etched. Silicon oxide is a substance that is insoluble or hardly soluble in an alkaline etching solution containing a quaternary ammonium hydroxide.

The plurality of polysilicon films P1 to P3 and the plurality of polysilicon oxide films O1 to O3 are multi-layered in the thickness direction Dt of the substrate W such that the polysilicon film and the silicon oxide film are alternated with each other. The polysilicon films P1 to P3 are thin films which are obtained by a deposition step of depositing polysilicon on the substrate W and a heat treatment step of heating the deposited polysilicon (see FIG. 4). The polysilicon films P1 to P3 may be thin films which are not subjected to the heat treatment step.

As shown in FIG. 4, the concave portion 92 penetrates the plurality of polysilicon films P1 to P3 and the plurality of silicon oxide films O1 to O3 in the thickness direction Dt of the substrate W. Side surfaces of the polysilicon films P1 to P3 and the silicon oxide films O1 to O3 are exposed at the side surface 92s of the concave portion 92. The concave portion 92 may be any of a trench, a via hole, and a contact hole, or may be other forms.

Before the treatment (etching) shown in FIG. 5 is started, a natural oxide film is formed on surface layers of the polysilicon films P1 to P3 and the silicon oxide films O1 to O3. A two-dot chain line on the left side in FIG. 4 shows an outline of the natural oxide film.

Hereinafter, an example of treatment of the substrate W performed by the substrate treatment device 1 is described with reference to FIGS. 2, 3, and 5. In the substrate treatment device 1, steps after START in FIG. 5 are continued.

When the substrate W is treated by the substrate treatment device 1, a carry-in step of carrying the substrate W into the chamber 4 is performed (step S1 in FIG. 5).

Specifically, while all the guards 21 located at the lower position, the center robot CR inserts the hand H1 into the chamber 4 while supporting the substrate W with the hand H1. Then, the center robot CR places the substrate W on the hand H1 onto the plurality of chuck pins 11 with a surface of the substrate W facing upward. Thereafter, the plurality of chuck pins 11 are pressed against the outer peripheral surface of the substrate W, and a substrate holding step of holding the substrate W in a horizontal posture is performed. After placing the substrate W onto the spin chuck 10, the center robot CR retracts the hand H1 from an inside of the chamber 4.

Next, the spin motor 13 is driven and rotation of the substrate W is started (step S2 in FIG. 5). As a result, the substrate is rotated around a vertical rotation axis that passes through a center portion of the substrate.

Next, a first chemical solution supply step of supplying DHF, which is an example of the first chemical solution, to an upper surface of the substrate W is performed (step S3 in FIG. 5).

Specifically, a first chemical solution valve of the first chemical solution discharge unit 41 is opened, and discharge of DHF is started. DHF discharged from the first chemical solution discharge unit 41 collides with a central portion of the upper surface of the substrate W, and then flows outward along the upper surface of the substrate W which is rotating. Accordingly, a solution film of DHF covering the entire upper surface of the substrate W is formed, and DHF is supplied to the entire upper surface of the substrate W. When a predetermined time elapses after the first chemical solution valve is opened, the first chemical solution valve is closed and discharge of DHF is stopped.

Next, a first rinse solution supply step of supplying pure water, which is an example of the rinse solution, to the upper surface of the substrate W is performed (step S4 in FIG. 5).

Specifically, a rinse solution valve of the rinse solution discharge unit 43 is opened, and the rinse solution discharge unit 43 starts discharge of pure water. Pure water that collides with the central portion of the upper surface of the substrate W flows outward along the upper surface of the substrate W which is rotating. DHF on the substrate W is washed away by pure water discharged from the rinse solution discharge unit 43. Accordingly, a solution film of pure water covering the entire upper surface of the substrate W is formed. When a predetermined time elapses after the rinse solution valve is opened, the rinse solution valve is closed and discharge of pure water is stopped.

Next, a second chemical solution supply step of supplying a silicon etching solution, which is the second chemical solution, to the upper surface of the substrate W is performed (step S5 in FIG. 5).

Specifically, a second chemical solution valve of the second chemical solution discharge unit 42 is opened, and the second chemical solution discharge unit 42 starts discharge of an etching solution. Before discharge of the etching solution is started, the guard elevating unit may move at least one guard 21 vertically in order to switch the guard 21 that receives a liquid discharged from the substrate W. The etching solution that collides with the central portion of the upper surface of the substrate W flows outward along the upper surface of the substrate W which is rotating. Pure water on the substrate W is replaced with the etching solution discharged from the second chemical solution discharge unit 42. Accordingly, a solution film of the etching solution covering the entire upper surface of the substrate W is formed. When a predetermined time elapses after the second chemical solution valve is opened, the second chemical solution valve is closed and discharge of the etching solution is stopped.

Next, a second rinse solution supply step of supplying pure water, which is an example of the rinse solution, to the upper surface of the substrate W is performed (step S6 in FIG. 5).

Specifically, a rinse solution valve of the rinse solution discharge unit 43 is opened, and the rinse solution discharge unit 43 starts discharge of pure water. Pure water that collides with the central portion of the upper surface of the substrate W flows outward along the upper surface of the substrate W which is rotating. The etching solution on the substrate W is washed away by pure water discharged from the rinse solution discharge unit 43. Accordingly, a solution film of pure water covering the entire upper surface of the substrate W is formed. When a predetermined time elapses after the rinse solution valve is opened, the rinse solution valve is closed and the discharge of pure water is stopped.

Next, a drying step of drying the substrate W by rotating the substrate W is performed (step S7 in FIG. 5).

Specifically, the spin motor 13 accelerates the rotation of substrate W in a rotation direction and rotates the substrate W at a rotation speed (for example, thousands of rpm) higher than a rotation speed of the substrate W in a period from the first chemical solution supply step to the second rinse solution supply step. Accordingly, the liquid is removed from the substrate W and the substrate W is dried. When a predetermined time elapses from a start of high-speed rotation of the substrate W, the spin motor 13 stops rotating. Accordingly, the rotation of the substrate W is stopped (step S8 in FIG. 5).

Next, a carry-out step of carrying the substrate W out of the chamber 4 is performed (step S9 in FIG. 5).

Specifically, the guard elevating unit lowers all the guards 21 to the lower position. Thereafter, the center robot CR inserts the hand H1 into the chamber 4. The center robot CR supports the substrate W on the spin chuck 10 with the hand H1 after the plurality of chuck pins 11 release holding of the substrate W. Then, the center robot CR retracts the hand H1 from the inside of the chamber 4 while supporting the substrate W with the hand H1. Accordingly, a treated substrate W is taken out of the chamber 4.

As described above, in a preferred embodiment of the present invention, the above silicon etching solution is supplied to the substrate W in which the polysilicon films P1 to P3 (see FIG. 4) and the silicon oxide films O1 to O3 (see FIG. 4) different from the polysilicon films P1 to P3 are exposed.

In the present embodiment, DHF, which is an example of an oxide film removing solution, is supplied to the substrate W, and the natural oxide film of the polysilicon films P1 to P3 is removed from the surface layers of the polysilicon films P1 to P3. Thereafter, the etching solution is supplied to the substrate W, and the polysilicon films P1 to P3, which are the targets to be etched, are selectively etched. The natural oxide film of the polysilicon films P1 to P3 mainly contains silicon oxide. The etching solution is a liquid that etches the polysilicon films P1 to P3 with no etching or little etching of silicon oxide. This is because a hydroxide ion reacts with silicon, but does not react with or hardly reacts with silicon oxide. Therefore, by removing the natural oxide film of the polysilicon films P1 to P3 in advance, the polysilicon films P1 to P3 can be efficiently etched.

In the present embodiment, the etching targets P1 to P3, which are subjected to the heat treatment step of heating the deposited polysilicon, are etched with the alkaline etching solution. When the deposited polysilicon is heated under an appropriate condition, a grain size of polysilicon increases. Therefore, the size of the silicon single crystal contained in the etching targets P1 to P3 is larger than that in a case where the heat treatment step is not performed. This means that the number of silicon single crystals exposed on surfaces of the etching targets P1 to P3 is reduced, and an influence of anisotropy is increased. Therefore, the influence of the anisotropy can be effectively reduced by supplying, to such etching targets P1 to P3, the etching solution containing the quaternary ammonium hydroxide, water, and the at least one compound selected from the compounds represented by Formula (1) and Formula (2).

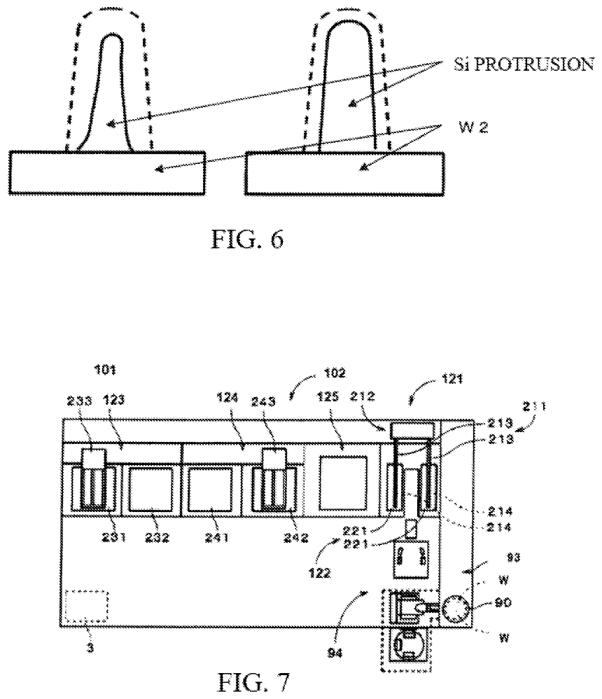

FIG. 6 is another example of treating a substrate W2 performed by the substrate treatment device 1. In the example shown in FIG. 6, the substrate W2 having a fin-shaped Si protrusion is subjected to the treatment (etching) shown in FIG. 5. When treating the substrate W2 having the fin-shaped Si protrusion as shown in FIG. 6, conventionally, an etching amount varies as shown on the left side in FIG. 6 due to crystal anisotropy during silicon etching. The right side in FIG. 6 shows a cross section of the substrate W2 after being treated with the etching solution of the present invention. As shown on the right side in FIG. 6, when the substrate W2 is etched, the crystal anisotropy in etching the fin-shaped Si protrusion of the substrate W2 is prevented, and the substrate W2 can be etched isotropically. The dotted line in FIG. 6 shows a shape before the treatment.

In the present embodiment, the treatment unit 2 may include a blocking member provided above the spin chuck 10. The blocking member includes a disc portion provided above the spin chuck 10 and a tubular portion extending downward from an outer peripheral portion of the disc portion.

Next, a second embodiment is described.

A main difference of the second embodiment from the first embodiment is that a substrate treatment device 101 is a batch type device that collectively treats the plurality of substrates W.

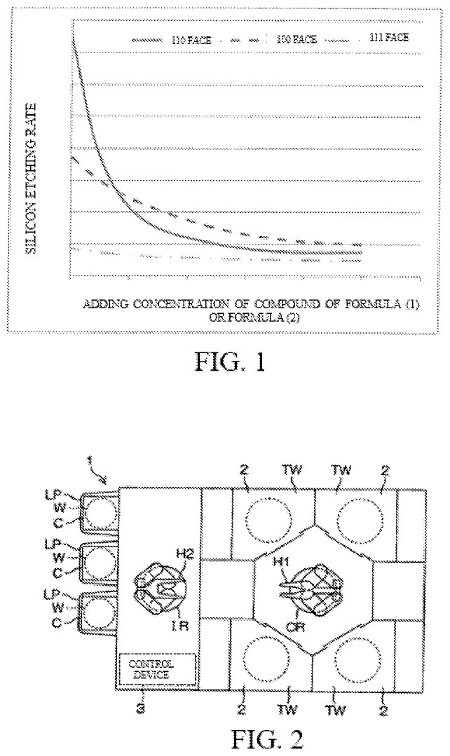

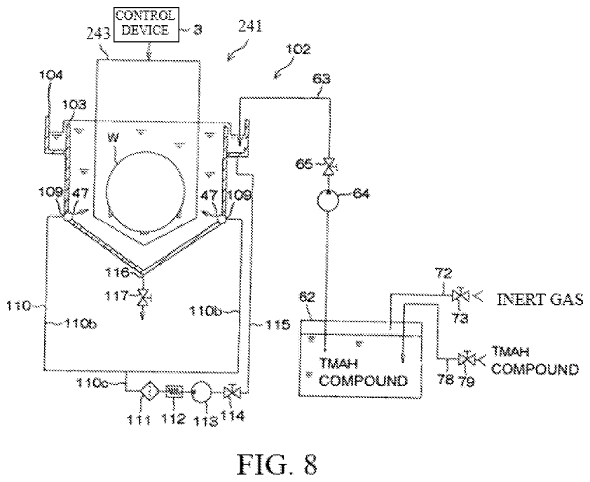

FIG. 7 is a schematic plan view showing a layout of the substrate treatment device 101 according to the second embodiment of the present invention. FIG. 8 is a schematic view showing a treatment unit 102 provided in the substrate treatment device 101 according to the second embodiment of the present invention. In FIGS. 7 to 9, the same reference numerals as those in FIG. 1 are added to the same configurations as those shown in FIGS. 1 to 5 and the description thereof are be omitted.

As shown in FIG. 7, the substrate treatment device 101 is roughly divided into the control device 3, a cassette holding unit 93, a posture changing unit 94, and the treatment unit 102, and the cassette holding unit 93, the posture changing unit 94, and the treatment unit 102 are controlled by the control device 3. The cassette holding unit 93 holds a cassette 90 accommodating the plurality of substrates W stacked in a horizontal posture in which main surfaces face a vertical direction. In the posture changing unit 94, the plurality of substrates W before the treatment are taken out of the cassette 90, a posture of the plurality of substrates W is changed into an upright posture in which the main surfaces face the horizontal direction, and the plurality of substrates W are delivered to the treatment unit 102. The plurality of substrates W treated in the treatment unit 102 are delivered from the treatment unit 102 to the posture changing unit 94 in the upright posture, the plurality of substrates W are changed into a horizontal state in which the main surfaces face in a direction perpendicular to a surface, and then the plurality of substrates W are collectively returned to the cassette 90 of the cassette holding unit 93.

The treatment unit 102 includes a main convey mechanism 121, a transfer unit cleaning unit 122, a first chemical solution treatment unit 123, a second chemical solution treatment unit 124, and a drying treatment unit 125, and the first chemical solution treatment unit 123, the second chemical solution treatment unit 124, the drying treatment unit 125, and the transfer unit cleaning unit 122 are arranged in this order in FIG. 7. The first chemical solution treatment unit 123 includes a first chemical solution tank 231 in which a predetermined chemical solution is stored, a first rinse solution tank 232 in which a rinse solution is stored, and a first lifter 233 configured to collectively convey the plurality of substrates W from the first chemical solution tank 231 to the first rinse solution tank 232. Similar to the first chemical solution treatment unit 123, the second chemical solution treatment unit 124 also includes a second chemical solution tank 241 in which a predetermined chemical solution is stored, a second rinse solution tank 242 in which a rinse solution is stored, and a second lifter 243 configured to collectively convey the plurality of substrates W from the second chemical solution tank 241 to the second rinse solution tank 242.

The main convey mechanism 121 includes a transfer unit 211 configured to support and elevate the plurality of substrates W, and a transfer unit moving mechanism 212 configured to move the transfer unit 211 between the transfer unit cleaning unit 122, the first chemical solution treatment unit 123, the second chemical solution treatment unit 124, and the drying treatment unit 125. The transfer unit 211 includes a pair of support arms 213 arranged at an interval, an arm drive unit configured to change the interval between the pair of support arms 213, and an arm elevating unit configured to elevate the pair of support arms 213 in the vertical direction. A support member 214 is provided on a lower portion of each support arm 213, and a plurality of grooves are formed in the support member 214 at a constant pitch from a tip toward a root of each support arm 213. The arm drive unit changes an interval between the pair of support members 214 by rotating each support arm 213 around an axis parallel to an axis from the tip toward the root of each support arm 213.

In the substrate treatment device 101, the plurality of substrates W are conveyed into the treatment unit 102 in the upright posture in which the substrates are stacked in such manner that the main surfaces thereof are in parallel from the tip toward the root of each support arm 213 by the posture changing unit 94, and edges of the substrates W are arranged and supported in the above grooves by the pair of support members 214. The interval between the pair of support members 214 is either a width at the time of sandwiching the plurality of substrates W by the pair of support members 214 (a width smaller than a diameter of the substrate W, hereinafter referred to as the “sandwiching width”) or a width at the time of releasing the plurality of substrates W from the pair of support members 214 (a width larger than the diameter of the substrate W, hereinafter referred to as the “releasing width”).

The transfer unit cleaning unit 122 includes two cleaning tanks 221 arranged vertically in a lower side of the pair of support members 214. Each cleaning tank 221 is provided with a nozzle for ejecting a cleaning solution and a nozzle for ejecting a nitrogen gas. At the time of cleaning the transfer unit 211, the pair of support members 214 (and parts of the support arms 213) are arranged in the two cleaning tanks 221. The support member 214 is cleaned with the cleaning solution, and then the cleaning solution adhering to the support members 214 is removed by the nitrogen gas (that is, the support members 214 are dried).

When the substrates W are treated by the chemical solution treatment units 123 and 124, the transfer unit 211 configured to sandwich the plurality of substrates W is arranged above the chemical solution tanks 231 and 241, and the first lifter 233 and the second lifter 243 in the chemical solution tanks 231 and 241 move upward. The first lifter 233 and the second lifter 243 are each provided with a plurality of claws for supporting the substrates W in the upright posture from below. After the substrates W come into contact with the claws, the interval between the pair of support members 214 is widened to the releasing width, so that the plurality of substrates W are transferred from the transfer unit 211 to the first lifter 233 and the second lifter 243. In the chemical solution treatment units 123 and 124, the first lifter 233 and the second lifter 243 are lowered, so that the plurality of substrates W are arranged in the chemical solution tanks 231 and 241 and the treatment with the chemical solution is collectively performed on the plurality of substrates W.

When the treatment with the chemical solution is completed, the first lifter 233 and the second lifter 243 are raised, and then move to the upper portion of the rinse solution tanks 232 and 242. Then, the first lifter 233 and the second lifter 243 are lowered, so that the plurality of substrates W are arranged in the rinse solution tanks 232 and 242, and the treatment with the rinse solution is collectively performed on the plurality of substrates W. When the treatment with the rinsing solution is completed, the first lifter 233 and the second lifter 243 are raised, and the substrates W are arranged to the upper portion of the rinsing solution tanks 232 and 242. At this time, the transfer unit 211 is also arranged at the upper portion of the rinse solution tanks 232 and 242, and the plurality of substrates W are located between the pair of support members 214 whose interval is widened to the releasing width. After the interval between the pair of support members 214 is narrowed to the sandwiching width, the first lifter 233 and the second lifter 243 are lowered, so that the plurality of substrates W are transferred from the first lifter 233 and the second lifter 243 to the transfer unit 211.

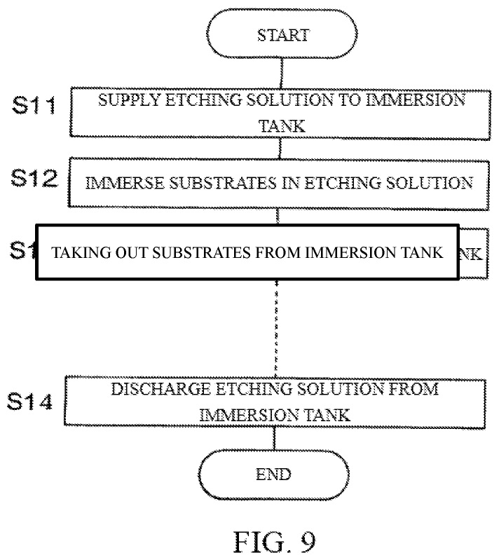

Specifically, all the substrates W included in one batch are transferred to the first lifter 233 of the first chemical solution treatment unit 123 by the main transport mechanism 121 and are immersed in the first chemical solution in the first chemical solution tank 231. For example, the first chemical solution is DHF (diluted hydrofluoric acid). The first chemical solution may be a solution containing at least one of chemical solutions (for example, hydrofluoric acid, buffered hydrofluoric acid, and aqueous ammonia) that can remove a natural oxide film of a substrate. All the substrates W included in one batch and immersed in the first chemical solution are moved to the upper portion of the first rinse solution tank 232 by the first lifter 233 and are immersed in the first rinse solution in the first rinse solution tank 232. The first rinse solution is pure water (deionized water). A rinse solution other than pure water may be used. Regarding all the substrates W included in one batch and immersed in the first rinse solution, the first lifter 233 is raised, and all the substrates are transferred to the main convey mechanism 121 and then transferred to the second lifter 243 of the second chemical solution treatment unit 124. The second chemical solution is the silicon etching solution of the present invention. The second chemical solution is written as TMAH COMPOUND in FIG. 8. All the substrates W included in one batch and transferred to the second lifter 243 are immersed in an etching solution in an immersion tank 103 of the second chemical solution tank 241 and then taken out of the immersion tank 103 (step S13 in FIG. 9). All the substrates W included in one batch and taken out of the immersion tank 103 are immersed in the second rinse solution tank 242. The second rinse solution is pure water (deionized water). The second rinse solution may be a rinse solution other than pure water. All the substrates W included in one batch and transferred to the second lifter 243 are dried by the drying treatment unit 125 via the main convey mechanism 121.

FIG. 8 is a diagram illustrating the chemical solution tank 241 of the second chemical solution treatment unit 124 of the treatment unit 102. In FIG. 8, the treatment unit 102 configured to simultaneously supply an alkaline etching solution corresponding to the second chemical solution to the plurality of substrates W is included. The treatment unit 102 includes the immersion tank 103 in which an etching solution is stored and into which the plurality of substrates W are simultaneously transferred, and an overflow tank 104 that receives the etching solution overflowing from the immersion tank 103.

In addition to the immersion tank 103 and the overflow tank 104, the treatment unit 102 further includes the second lifter 243 configured to elevate while simultaneously holding the plurality of substrates W between a lower position where the plurality of substrates W are immersed in the etching solution in the immersion tank 103 and an upper position where the plurality of substrates W are located to the upper portion of the etching solution in the immersion tank 103.

The treatment unit 102 includes two chemical solution nozzles 109 each provided with a second chemical solution discharge port 47 configured to discharge an alkaline etching solution corresponding to the second chemical solution, and a drainage pipe 116 configured to discharge a liquid in the immersion tank 103. When the chemical solution nozzle 109 discharges the etching solution, the etching solution is supplied into the immersion tank 103, and an ascending stream is formed in the etching solution in the immersion tank 103. When a drainage valve 117 interposed in the drainage pipe 116 is opened, the liquid in the immersion tank 103, such as the etching solution, is discharged to the drainage pipe 116. An upstream end of the drainage pipe 116 is connected to a bottom portion of the immersion tank 103.

The overflow tank 104 is connected to, via a return pipe 115, a chemical solution pipe 110 including a common pipe 110c configured to guide the etching solution in the overflow tank 104 toward the two chemical solution nozzles 109, and two branch pipes 110b configured to guide the etching solution supplied from the common pipe 110c to the two chemical solution nozzles 109. An upstream end of the return pipe 115 is connected to the overflow tank 104, and a downstream end of the return pipe 115 is connected to the chemical solution valve 114. The etching solution overflowing from the immersion tank 103 to the overflow tank 104 is sent to the two chemical solution nozzles 109 again by a pump 113 arranged downstream of the chemical solution valve 114 and is filtered by a filter 111 before reaching the two chemical solution nozzles 109. The treatment unit 102 may include a temperature controller 112 configured to change a temperature of the etching solution in the immersion tank 103 by heating or cooling the etching solution.

When an empty immersion tank 103 is filled with an etching solution, a chemical solution valve 65 interposed in a pipe 63 configured to supply the etching solution to the overflow tank 104 is opened, and the etching solution stored in a tank 62 is sent to the overflow tank 104 by a pump 64. Subsequently, the chemical solution valve 114 interposed in the common pipe 110c is opened. Accordingly, the etching solution in the overflow tank 104 is sent into the common pipe 110c, supplied to the two chemical solution nozzles 109 via the two branch pipes 110b, and discharged from the two chemical solution nozzles 109 into the immersion tank 103. Then, when an inside of the immersion tank 103 is filled with the etching solution, the chemical solution valve 65 is closed and the supply of the etching solution from the tank 62 to the immersion tank 103 is stopped. The chemical valve 65 may be closed except a case where the empty immersion tank 103 is filled with the etching solution.

The tank 62 stores a mixed solution of the quaternary ammonium hydroxide and the compound represented by the above Formula (1) or Formula (2), and the quaternary ammonium hydroxide and the compound may be supplied as a mixed solution into the tank 62 by opening a chemical solution valve 79 interposed in a pipe 78, or may be supplied separately. In the tank 62, a valve 73 interposed in a pipe 72 may be opened to supply an inert gas. Accordingly, an upper space of the tank 62 can be filled with the inert gas, and a contact between the mixed solution stored in the tank 62 and oxygen can be prevented.

FIG. 9 is a process diagram showing an example of a flow from supply of a new etching solution to discharge of a used-up etching solution from the immersion tank 103. An operation described later is performed by the control device 3 controlling the substrate treatment device 101. In other words, the control device 3 is programmed to cause the substrate treatment device 101 to perform the following operation. Hereinafter, reference is made to FIGS. 8 and 9.

The etching solution to be supplied to the immersion tank 103 of the treatment unit 102 is stored in the tank 62. Thereafter, the chemical solution valves 65 and 114 are opened, and the etching solution is supplied from the tank 62 to the overflow tank 104 by driving the pump 64. The etching solution supplied to the overflow tank 104 is sent into the common pipe 110c by opening the chemical solution valve 114 connected to the common pipe 110c. The etching solution in the common pipe 110c is supplied to the two chemical solution nozzles 109 via the two branch pipes 110b, and supply of the etching solution from the two chemical solution nozzles 109 to the immersion tank 103 is started (step S11 in FIG. 9). When the inside of the immersion tank 103 is filled with the etching solution, the chemical solution valve 65 is closed and supply of the etching solution from the tank 62 to the immersion tank 103 is stopped.

After the etching solution is supplied, the second lifter 243 lowers the plurality of substrates W from the upper position to the lower position while holding the plurality of substrates W in the upright posture. Accordingly, all the substrates W included in one batch are immersed in the etching solution in the immersion tank 103 in the upright posture (step S12 in FIG. 9). Therefore, the etching solution is simultaneously supplied to the plurality of substrates W, and the etching targets, such as the polysilicon films P1 to P3 (see FIG. 4), are etched. When a predetermined time elapses after the second lifter 243 moves to the lower position, the second lifter 243 rises to the upper position.

The series of flow is repeated for each batch. That is, when all the substrates W included in one batch are taken out of the immersion tank 103 (step S13 in FIG. 9), similar as described above, all the substrates W included in another batch are immersed in the etching solution in the immersion tank 103 and etched. When the number of etchings or a usage time of the etching solution in the immersion tank 103 reaches an upper limit value, the etching solution in the immersion tank 103 is replaced with a new etching solution.

Specifically, the drainage valve 117 is opened, and the etching solution in the immersion tank 103 is discharged to the drainage pipe 116 (step S14 in FIG. 9). When the inside of the immersion tank 103 is empty, a new etching solution is supplied to the immersion tank 103 (step S11 in FIG. 9).

### EXAMPLES

Hereinafter, the present invention is described in more detail with reference to Examples, but the present invention is not limited to these Examples.

### Example 1

A silicon etching solution having a composition shown in Table 1 was prepared using tetramethylammonium hydroxide (TMAH) as the quaternary ammonium hydroxide, and using diethylene glycol monobutyl ether as the compound represented by Formula (1). The remnant is pure water.

<Evaluation of Etching Rate Ratio and Surface Roughness on Silicon Substrate in Each Crystal Orientation>

N₂ gas was bubbled and aerated in the silicon etching solution heated to a solution temperature of 40° C. until a dissolved oxygen concentration dropped to a constant concentration value, then a silicon substrate was immersed in the aerated silicon etching solution for 2 hours, and an etching rate for silicon at the solution temperature of 40° C. was measured. The target silicon substrates were silicon substrates with crystal orientations (100 plane, 110 plane, and 111 plane) whose native oxide film was removed with a chemical solution. The etching rate was obtained by measuring weights of the silicon substrate before and after etching for the silicon substrate on respective crystal orientations (100 plane, 110 plane, and 111 plane), converting the weight difference before and after the treatment into an etching amount of the silicon substrate, and dividing the etching amount by an etching time. Next, etching rate ratios (R₁₁₀/R₁₀₀) and (R₁₁₀/R₁₁₁) for the silicon substrates on respective crystal orientation (100 plane, 110 plane, and 111 plane) were calculated. Surface conditions of the silicon substrate with respective crystal orientations (100 plane, 110 plane, and 111 plane) were observed from the appearance thereof and evaluated according to the following criteria. Results are shown in Table 2.

<Evaluation Criteria of Surface Roughness on Silicon Substrate in Each Crystal Orientation>

5: No white turbidity can be seen on a wafer surface, and the surface is a mirror surface.

3: A slight white turbidity can be seen on a wafer surface, but the surface is a mirror surface.

1: A wafer surface is completely white and turbid, but a mirror surface remains.

0: A wafer surface is completely white and turbid, and a mirror surface is lost due to severe surface roughness.

Those in which the evaluation results for the 100 plane, the 110 plane, and the 111 plane were each 3 or more and a total of the evaluation results was 11 or more were uniformly etched in each crystal orientation and evaluated as a good isotropic property.

<Evaluation for Selective Ratio of Silicon to Silicon Oxide Film and Silicon Nitride Film>

N₂ gas was bubbled and aerated in the silicon etching solution heated to a solution temperature of 40° C. until a dissolved oxygen concentration dropped to a constant concentration value, then a silicon oxide film and a silicon nitride film were immersed in the aerated silicon etching solution for 10 minutes, and etching rates of the silicon oxide film and the silicon nitride film at the solution temperature of 40° C. were measured. The etching rate was obtained by measuring film thicknesses of the silicon oxide film or the silicon nitride film before and after the etching with a spectroscopic ellipsometer, converting a difference in film thicknesses before and after the treatment into an etching amount of the silicon oxide film or the silicon nitride film, and dividing the etching amount by an etching time. Next, the etching rate ratio (R₁₀₀/silicon oxide film) and (R₁₀₀/silicon nitride film) with respect to the silicon substrate (100 plane) was calculated and evaluated according to the following criteria. Results are shown in Table 2.

<Evaluation Criteria of Selective Ratios of Silicon to Silicon Oxide Film and Silicon Nitride Film>

A selective ratio of silicon to the silicon oxide film (Si (100 plane)/SiO₂)

A: 1000 or more, B: 700 or more and less than 1,000, C: 500 or more and less than 700, D: less than 500

A selective ratio of silicon to the silicon nitride film (Si (100 plane)/SiN)

A: 1,000 or more, B: 700 or more and less than 1,000, C: 500 or more and less than 700, D: less than 500

A selective ratio of B and thereabove are evaluated as good selectivity. Here, the selective ratio (Si (100 plane)/SiO₂) of potassium hydroxide (KOH), which is an inorganic alkali, is about 250 and is classified as D according to the above evaluation criteria.

### Examples 2 to 32

An evaluation was performed in the same manner as in Example 1 except that a silicon etching solution having a composition shown in Table 1 was used as the silicon etching solution. “Choline” in the table indicates trimethyl-2-hydroxyethylammonium hydroxide (choline hydroxide). Results are shown in Table 2.

### Comparative Examples 1 to 9

An evaluation was performed in the same manner as in Example 1 except that a silicon etching solution having a composition shown in Table 1, which did not contain the compounds represented by Formula (1) and Formula (2). Results are shown in Table 2.

Regarding Example 10 and Comparative Example 1, surface Ra values (unit: nm) of the silicon substrate with respective crystal orientations (100 plane, 110 plane, and 111 plane) were measured, and results are shown in Table 3. The surface Ra value was a value at the time of observing the 100 plane, 110 plane, and 111 plane with a viewing angle of 175 μm by using a 50× lens of an optical interference microscope. It can be seen from Table 2 that evaluation results of surface appearance and the surface Ra values are consistent. A polycrystalline silicon (poly-Si) plate was separately prepared and etched in the same manner as above, and a surface Ra value of the plate was measured at a viewing angle of 1.5 μm by using an atomic force microscope (AFM).

TABLE 1

| | Silicon etching solution | | | | | | | |
|---|---|---|---|---|---|---|---|---|
| | Quaternary | Content | | Content | Compaund | Content | | Content |
| | ammonium | (mass | | (mass | represented by | (mass | | (mass |
| | hydroxide | %) | Compound represented by Formula (1) | %) | Formula (2) | %) | Others | %) |
| Example 1 | TMAH | 5 | Diethylene glycol monobutyl ether | 10 | | | | |
| Example 2 | TMAH | 5 | Diethylene glycol monobutyl ether | 20 | | | | |
| Example 3 | TMAH | 5 | Diethylene glycol monobutyl ether | 40 | | | | |
| Example 4 | TMAH | 5 | Propylene glycol monoethyl ether | 10 | | | | |
| Example 5 | TMAH | 5 | Propylene glycol monoethyl ether | 20 | | | | |
| Example 6 | TMAH | 1 | Propylene glycol monopropyl ether | 2 | | | | |
| Example 7 | TMAH | 5 | Propylene glycol monopropyl ether | 4 | | | | |
| Example 8 | TMAH | 5 | Propylene glycol monopropyl ether | 10 | | | | |
| Example 9 | TMAH | 5 | Propylene glycol monobutyl ether | 10 | | | | |
| Example 10 | TMAH | 5 | Dipropylene glycol monopropyl ether | 5 | | | | |
| Example 11 | TMAH | 5 | Triethylene glycol monobutyl ether | 10 | | | | |
| Example 12 | TMAH | 5 | Triethylene glycol monobutyl ether | 20 | | | | |
| Example 13 | TMAH | 5 | Triethylene glycol monobutyl ether | 40 | | | | |
| Example 14 | TMAH | 5 | Tripropylene glycol monomethyl ether | 10 | | | | |
| Example 15 | TMAH | 5 | Tripropylene glycol monomethyl ether | 20 | | | | |
| Example 16 | TMAH | 5 | | | Polyethylene | 2 | | |
| | | | | | glycol 1000 | | | |
| Example 17 | TMAH | 5 | | | Polyethylene | 2 | | |
| | | | | | glycol 1540 | | | |
| Example 18 | TMAH | 0.1 | | | Polyethylene | 0.1 | | |
| | | | | | glycol 4000 | | | |
| Example 19 | TMAH | 1 | | | Polyethylene | 0.1 | | |
| | | | | | glycol 4000 | | | |
| Example 20 | TMAH | 3 | | | Polyethylene | 0.1 | | |
| | | | | | glycol 4000 | | | |
| Example 21 | TMAH | 5 | | | Polyethylene | 0.1 | | |
| | | | | | glycol 4000 | | | |
| Example 22 | TMAH | 10 | | | Polyethylene | 0.1 | | |
| | | | | | glycol 4000 | | | |
| Example 23 | TMAH | 5 | | | Polyethylene | 0.05 | | |
| | | | | | glycol 4000 | | | |
| Example 24 | TMAH | 5 | | | Polyethylene | 0.01 | | |
| | | | | | glycol 4000 | | | |
| Example 25 | TMAH | 5 | | | Polyethylene | 2 | | |
| | | | | | glycol 20000 | | | |
| Example 26 | TMAH | 5 | Propylene glycol monomethyl ether | 5 | | | | |
| | | | Propylene glycol monopropyl ether | 5 | | | | |
| Example 27 | TMAH | 5 | | | Polyethylene | 0.05 | | |
| | | | | | glycol 1000 | | | |
| | | | | | Polyethylene | 0.05 | | |
| | | | | | glycol 4000 | | | |
| Example 28 | Choline | 3.6 | Diethylene glycol monobutyl ether | 10 | | | | |
| Example 29 | Choline | 6.6 | Diethylene glycol monobutyl ether | 10 | | | | |
| Example 30 | Choline | 6.6 | Propylene glycol monopropyl ether | 10 | | | | |
| Example 31 | Choline | 6.6 | Triethylene glycol monobutyl ether | 10 | | | | |
| Example 32 | Choline | 6.6 | Tripropylene glycol monomethyl ether | 20 | | | | |
| Comparative | TMAH | 0.1 | | | | | | |
| Example 1 | | | | | | | | |
| Comparative | TMAH | 1 | | | | | | |
| Example 2 | | | | | | | | |
| Comparative | TMAH | 5 | | | | | | |
| Example 3 | | | | | | | | |
| Comparative | TMAH | 10 | | | | | | |
| Example 4 | | | | | | | | |
| Comparative | TMAH | 5 | | | | | 1,5-butanediol | 10 |
| Example 5 | | | | | | | | |
| Comparative | TMAH | 5 | | | | | Diethylene glycol | 10 |
| Example 6 | | | | | | | monomethyl ether | |
| Comparative | TMAH | 5 | | | | | Polyethylene glycol | 1 |
| Example 7 | | | | | | | 200 | |
| Comparative | Choline | 3.6 | | | | | | |
| Example 8 | | | | | | | | |
| Comparative | Choline | 6.6 | | | | | | |
| Example 9 | | | | | | | | |

TABLE 2

| | | | Surface appearance evaluation (5, 3, 1, 0) | | | | Selective ratio | |
|---|---|---|---|---|---|---|---|---|
| | Etching rate ratio | | 100 | 110 | 111 | Total | evaluation (A to E) | |
| | R₁₁₀/R₁₀₀ | R₁₁₀/R₁₁₁ | plane | plane | plane | score | Si/SiO₂ | Si/SiN |
| Example 1 | 0.7 | 2.2 | 5 | 5 | 5 | 15 | A | A |
| Example 2 | 0.5 | 2.1 | 5 | 5 | 5 | 15 | A | A |
| Example 3 | 0.7 | 3.6 | 3 | 3 | 5 | 11 | A | A |
| Example 4 | 0.6 | 2.7 | 3 | 5 | 5 | 13 | A | A |
| Example 5 | 0.6 | 2.5 | 5 | 5 | 5 | 15 | A | A |
| Example 6 | 0.6 | 1.8 | 5 | 5 | 5 | 15 | A | A |
| Example 7 | 0.5 | 2.7 | 3 | 5 | 5 | 13 | A | A |
| Example 8 | 0.5 | 2.2 | 5 | 5 | 5 | 15 | A | A |
| Example 9 | 0.6 | 2.2 | 3 | 5 | 5 | 13 | A | A |
| Example 10 | 0.5 | 2.3 | 3 | 5 | 5 | 13 | A | A |
| Example 11 | 0.8 | 3.3 | 5 | 5 | 5 | 15 | A | A |
| Example 12 | 0.7 | 2.4 | 5 | 5 | 5 | 15 | A | A |
| Example 13 | 0.7 | 3.4 | 3 | 5 | 5 | 13 | A | A |
| Example 14 | 0.5 | 1.8 | 3 | 5 | 5 | 13 | A | A |
| Example 15 | 0.4 | 2.2 | 5 | 5 | 5 | 15 | A | A |
| Example 16 | 0.5 | 2.1 | 3 | 5 | 5 | 13 | A | A |
| Example 17 | 0.5 | 2.0 | 3 | 5 | 5 | 13 | A | A |
| Example 18 | 0.8 | 1.9 | 5 | 5 | 5 | 15 | A | A |
| Example 19 | 0.6 | 1.4 | 5 | 5 | 5 | 15 | A | A |
| Example 20 | 0.5 | 1.6 | 3 | 5 | 5 | 13 | A | A |
| Example 21 | 0.5 | 1.9 | 3 | 5 | 5 | 13 | A | A |
| Example 22 | 0.4 | 2.3 | 3 | 5 | 5 | 13 | A | A |
| Example 23 | 0.5 | 1.9 | 3 | 5 | 5 | 13 | A | A |
| Example 24 | 0.5 | 1.8 | 3 | 5 | 5 | 13 | A | A |
| Example 25 | 0.5 | 1.8 | 3 | 5 | 5 | 13 | A | A |
| Example 26 | 0.5 | 2.1 | 3 | 3 | 5 | 11 | A | A |
| Example 27 | 0.5 | 2.2 | 3 | 5 | 5 | 13 | A | A |
| Example 28 | 0.7 | 1.9 | 5 | 5 | 5 | 15 | A | A |
| Example 29 | 0.7 | 2.7 | 5 | 5 | 5 | 15 | A | A |
| Example 30 | 0.7 | 2.3 | 5 | 5 | 5 | 15 | A | A |
| Example 31 | 0.8 | 2.7 | 5 | 5 | 5 | 15 | A | A |
| Example 32 | 0.5 | 2.7 | 5 | 5 | 5 | 15 | A | A |
| Comparative | 0.7 | 4.5 | 0 | 1 | 3 | 4 | A | A |
| Example 1 | | | | | | | | |
| Comparative | 0.9 | 4.9 | 0 | 1 | 3 | 4 | A | A |
| Example 2 | | | | | | | | |
| Comparative | 1.7 | 6.0 | 0 | 1 | 3 | 4 | A | A |
| Example 3 | | | | | | | | |
| Comparative | 2.1 | 7.1 | 1 | 1 | 5 | 7 | A | A |
| Example 4 | | | | | | | | |
| Comparative | 1.4 | 4.4 | 1 | 1 | 5 | 7 | A | A |
| Example 5 | | | | | | | | |
| Comparative | 1.3 | 3.9 | 1 | 0 | 3 | 4 | A | A |
| Example 6 | | | | | | | | |
| Comparative | 1.2 | 3.8 | 0 | 1 | 5 | 6 | A | A |
| Example 7 | | | | | | | | |
| Comparative | 0.6 | 4.3 | 0 | 0 | 3 | 3 | A | A |
| Example 8 | | | | | | | | |
| Comparative | 0.6 | 4.3 | 0 | 0 | 3 | 3 | A | A |
| Example 9 | | | | | | | | |

TABLE 3

| | Surface state | | | | | | |
|---|---|---|---|---|---|---|---|
| | evaluation | | | | | | |
| | (5, 3, 1, 0) | | | Surface Ra value (nm) | | | |
| | 100 | 110 | 111 | 100 | 110 | 111 | Poly-Si |
| | plane | plane | plane | plane | plane | plane | face |
| Example | 5 | 5 | 5 | ≤3 | ≤3 | ≤3 | ≤3 |
| Comparative | 0 | 1 | 3 | 20 | 10 | ≤3 | 7 |
| Example 1 | | | | | | | |

| | | | | |
|---|---|---|---|---|
| Before treatment | ≤3 | ≤3 | ≤3 | ≤3 |

### REFERENCE SIGNS LIST

1, 101 substrate treatment device

2, 102 treatment unit

3 control device

4 chamber

10 spin chuck

11 chuck pin

12 spin base

13 spin motor

20 treatment cup

21 guard

22 cup

41 first chemical solution discharge unit

42 second chemical solution discharge unit

43 rinse solution discharge unit

47 chemical solution discharge port

62 tank

91 multi-layered film

92 concave portion

93 cassette holding unit

94 posture changing unit

103 immersion tank

104 overflow tank

109 chemical solution nozzle

110 chemical solution pipe

111 filter

112 temperature controller

113 pump

114 chemical solution valve

121 main convey mechanism

123 first chemical solution treatment unit

124 second chemical solution treatment unit

233 first lifter

243 second lifter

R1 recess

P1, P2, P3 polysilicon film

O1, O2, O3 silicon oxide film

LP load port

IR indexer robot

CR center robot

H1(H2) hand

What is claimed is:

1. An isotropic silicon etching solution, comprising:
a quaternary ammonium hydroxide;
water; and
at least one compound selected from the group consisting of compounds represented by the following Formulas (1) and (2), wherein
the following Conditions 1 and 2 are satisfied,
R¹O—(CₘH₂ₘO)n—R² (1)
wherein in the formula, R¹ is a hydrogen atom or an alkyl group having 1 to 3 carbon atoms, R² is a hydrogen atom or an alkyl group having 1 to 6 carbon atoms, m is an integer of 2 to 6, and n is 1 to 3; with the proviso that, R¹ and R² are not hydrogen atoms at the same time, and when m=2, a total number (n+C¹+C²) of n, the number of carbon atoms (C¹) of R¹, and the number of carbon atoms (C²) of R² is 5 or more, and
HO—(C₂H₄O)ₚ—H (2)
wherein in the formula, p is an integer of 15 to 1,000,
Condition 1: 0.2≤etching rate ratio (R₁₁₀/R₁₀₀)≤1
Condition 2: 0.8≤etching rate ratio (R₁₁₀/R₁₁₁)≤4
wherein in the above conditions, R₁₀₀ indicates an etching rate for a 100 plane of a silicon single crystal, R₁₁₀ indicates an etching rate for a 110 plane of the silicon single crystal, and R₁₁₁ indicates an etching rate for a 111 plane of the silicon single crystal.

2. The isotropic silicon etching solution according to claim 1, wherein a concentration of the quaternary ammonium hydroxide is 0.1 mass % to 25 mass %, and a concentration of the at least one compound selected from the compounds represented by Formula (1) and Formula (2) is 0.001 mass % to 40 mass %.

3. A substrate treatment method, comprising:
etching a silicon wafer and/or a substrate including a polysilicon film and an amorphous silicon film by using the isotropic silicon etching solution according to claim 1.

4. A method for manufacturing a silicon device, comprising:
etching a silicon wafer, a polysilicon film, or an amorphous silicon film, wherein
etching is performed by using the isotropic silicon etching solution according to claim 1.

5. A substrate treatment method, comprising:
holding a substrate in a horizontal posture; and
supplying the isotropic silicon etching solution according to claim 1 to an upper surface of the substrate while rotating the substrate around a vertical rotation axis passing through a central portion of the substrate.

6. A substrate treatment method, comprising:
holding a plurality of substrates in an upright posture; and
immersing, in the upright posture, the substrates in the isotropic silicon etching solution according to claim 1 which is stored in a treatment tank.
